(19) United States
(12) Patent Application Publication
(10) Pub. No.: US 2016/0138171 A1
(43) Pub. Date: May 19, 2016

(54) METHOD FOR MANUFACTURING CORROSION RESISTANT AND CONDUCTIVE NANO CARBON COATING LAYER AND FUEL CELL BIPOLAR PLATE THEREBY USING STAINLESS STEEL SUBSTRATE

(71) Applicant: J&L Tech Co., Ltd., Ansan-Si (KR)

(72) Inventors: Youngha Jun, Ansan-Si (KR); Jaimoo Yoo, Ansan-Si (KR); Kiho Yeo, Siheung-si (KR); Eui Chul Shin, Chuncheon-si (KR)

(21) Appl. No.: 14/885,077

(22) Filed: Oct. 16, 2015

Related U.S. Application Data
(62) Division of application No. 13/763,670, filed on Feb. 9, 2013, now abandoned.

(30) Foreign Application Priority Data
Jan. 22, 2013 (KR) 10-2013-0006803

(51) Int. Cl. C23F 1/12; H01J 37/32; H01M 8/1004; C23C 28/04

(52) U.S. Cl. CPC C23F 1/12; C23C 28/04; H01J 37/32899; H01M 8/1004; H01J 2237/3341; H01M 2008/1095

(57) ABSTRACT

The present invention proposed manufacturing device of coating layers with good conductivity and corrosion resistance at high productivity comprising etching the oxide layer on the stainless steel substrate by plasma etching to activate the surface and prevent from decreasing it's conductivity, coating metal nitrides like CrN or TiN in nano size thickness on the etched surface and coating carbon layer at nano size thickness on top of it. According to the present invention, it is possible to produce manufacture fuel cell bipolar plate, electrode material and stainless steel with reinforced conductivity and corrosion resistance in mass.

### CROSS-REFERENCE TO RELATED PATENT APPLICATION

This application is a divisional of U.S. patent application Ser. No. 13/763,670 filed Feb. 9, 2013, which claims the benefit of Korean Patent Applications No. 10-2013-0006803, filed on Jan. 22, 2013, in the Korean Intellectual Property Office, the disclosure of which is incorporated herein in its entirety by reference.

### BACKGROUND

1. Field of the Invention

The present invention is about special surface treatment method of stainless steel material so that it would have conductivity and corrosion resistance. In more detail, it is about a nano level thickness carbon coating method and manufacturing of PEMFC (Polymer Electrolyte Membrane Fuel Cell) bipolar plate and electrode material which has good conductivity and corrosion resistance.

2. Description of the Related Art

Stainless steel is quite commonly used material and it can be used in more various ways by complementing its property or reinforcing specific property of it. Stainless steel is getting attention as substrate material for fuel cell bipolar plate. It can be also used as material for electrode if the corrosion resistance of it can be reinforced. The reinforcement of other properties is also required for more diverse uses of stainless steel.

Fuel cell is one of environment-friendly new & renewable energy sources based on combustion reaction generating water and energy when hydrogen and oxygen react with each other with the existence of catalyst. It is possible to generate electric energy without generating specific pollutant. The efficiency of fuel cell is also very high when the generated heat would be summed up.

The fuel cell bipolar plate is an essential part in a fuel cell. As the properties which a fuel cell bipolar plate should have, there are strength, corrosion resistance, gas-blocking capability, conductivity and size accuracy. In addition, a fuel cell bipolar plate requires proper manufacturing process design in order for a fuel cell to be practical.

At present, two kinds of fuel cell bipolar plate are being developed in competition in order to meet above requirement. One is resin coating on carbon material and the other is surface treating of metal material. Republic of Korea Patent No. 10-1000697 suggests a technology which adopts coating carbon containing fluorine (F) on stainless steel; while JP 2010-287542-A suggests a technology which adopts coating chrome middle layer on stainless steel to improve the conductivity and coating carbon on top of it afterward. The carbon layer thickness of these technologies is relatively thick with thickness 0.5 μm˜2 μm; therefore, it is difficult to apply them on actual mass production.

When stainless steel is substrate, conductivity should be also good together with corrosion resistance; however, these two properties are rather incompatible with each other. The main stream of existing studies was on the surface reforming by nitrating stainless steel substrate; however, it was not possible to get satisfactory result for practicality both in cost and properties.

There was an attempt of gold-coating on stainless steel concentrating on the property improvement; however, it is difficult to commercialize it because it ignores cost.

FIG. 1 shows the contact resistance and corrosion current measurement result dependent on carbon coating temperature on stainless steel. Since a fuel cell bipolar plate should have both of these physical quantities low; it is required to take optimum coating temperature which would optimize the two.

FIG. 2 shows the contact resistance and corrosion current measurement result dependent on carbon coating layer thickness. It is possible to see that contact resistance and corrosion current decrease when layer thickness increases. However, a method keeping superior characteristics while keeping layer thickness thin is required because making the layer thick lowers productivity and it becomes a problem for mass production.

Meanwhile, in case of stainless steel, chrome(Cr) added for the improvement of corrosion resistance covers surface as a layer of oxides, which becomes a natural layer. It is required to deal with adhesiveness decrease of coating layer and conductivity decrease in surface treatment.

In addition, in case of carbon coating, achieving required property by making coating thick is not practical because a fuel cell bipolar plate should have low production cost and it can be produced in mass.

### SUMMARY

Accordingly, the purpose of the present invention is improving the properties by carbon-coating on the stainless steel substrate for better conductivity, corrosion resistance and coating layer adhesiveness, but still keeping coating layer as thin nano size film for good productivity and cheap costs.

Also, the present invention is to provide with a method of carbon coating with good conductivity and corrosion resistance in nano-size thickness together with relevant utilizing goods such as fuel cell bipolar plate and its manufacturing method.

### BRIEF DESCRIPTION OF THE FIGURES

FIG. 1 is a graph showing change in contact resistance and corrosion current dependent on the coating temperature of nano carbon coating material.

FIG. 2 is a graph showing change in contact resistance and corrosion current dependent on the thickness of nano carbon coating layer.

FIG. 3 is a layer cross-section showing the surface treatment and coating layer constitution of stainless steel substrate by the present invention.

FIG. 4 is a schematic diagram on carbon layer coating using ion gun by the present invention.

FIG. 5 is perspective diagram showing the in-line system of plasma etching of substrate, metal nitride layer coating and nano carbon layer coating by the present invention.

FIG. 6 is a graph showing the contact resistance and corrosion current of specimen completed of coating process by the present invention in comparison with conventional technology.

FIG. 7(a) and (b) are the figures explaining the contact resistance measurement method of specimen completed of coating process by the present invention.

FIG. 8 is a graph showing the etching rate dependent on the distance between ion gun and substrate during the plasma etching the oxide layer of the substrate by the present invention.

FIG. 9 is comparison images showing before-etching and the after-etching.

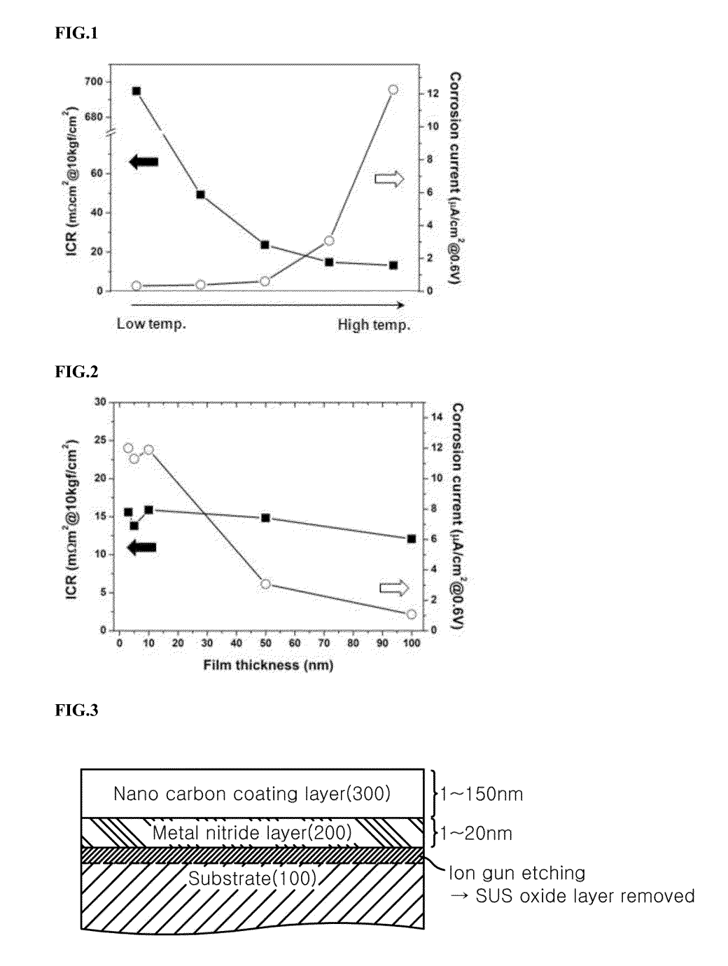

### DETAILED DESCRIPTION

In accordance with above purposes, in the present invention, the surface oxide layer of stainless steel substrate is etched by plasma to be vitalized and prevented the decrease in conductivity, coated on the etched layer with metal nitrides such as CrN and TiN in nano size thickness, and then coated with carbon layer in nano size in high productivity and excellent both conductivity and corrosion resistance. Plasma etching can remove the naturally formed oxide layer of the stainless steel which may deteriorate conductivity, and activate the surface to improve adhesion of coating layer.

In other words, the present invention provides with manufacturing method of nano carbon coating layer having corrosion resistance and conductivity comprise three steps of (1) etching the oxide layer of stainless steel substrate, (2) depositing metal nitride buffer layer in nano size thickness on the etched surface and (3) depositing conductive carbon layer on the above buffer layer in nano size thickness.

In addition, in the said manufacturing method the present invention provides with the manufacturing method of nano carbon coating layer with conductivity and corrosion resistance wherein the etching process of the oxide layer is embodied in adopting plasma etching.

In addition, in the said manufacturing method the present invention provides with the manufacturing method of nano carbon coating layer with conductivity and corrosion resistance wherein metal nitride buffer layer is formed by supplying metal target and nitrogen gas to a chamber, applying electric voltage on metal arc, applying bias voltage on the substrate and keeping the process temperature of 300 to 500° C.

In addition, in the said manufacturing method the present invention provides with the manufacturing method of nano carbon coating layer with conductivity and corrosion resistance wherein the deposition of conductive carbon layer comprises applying voltage on the ion gun, applying bias voltage on the substrate and coating at the temperature of 200 to 600° C.

In addition, in the said manufacturing method the present invention provides with the manufacturing method of nano carbon coating layer with conductivity and corrosion resistance wherein the bias voltage is DC, AC with voltage 0˜−800 V, or, pulse voltage with frequency 0.1 kHz-500 kHz and the conductive carbon layer is deposited in thickness of 1 to 150 nm.

In addition, in the said manufacturing method the present invention provides with the manufacturing method of nano carbon coating layer with conductivity and corrosion resistance wherein the three steps of (1) etching the oxide layer of stainless steel substrate, (2) depositing metal nitride layer in nano size thickness on the etched surface, and, (3) depositing conductive carbon layer on the above buffer layer in nano size is performed by constructing process chambers for each step and arranging each process chamber in-line and being proceeded in-situ consecutively.

In addition, in the said manufacturing method the present invention provides with the manufacturing method of nano carbon coating layer with conductivity and corrosion resistance wherein the step of etching the oxide layer comprises plasma etching adopting ion gun which is movable for reducing the distance between ion gun and substrate surface to improve the etching rate.

In addition, the present invention provides with stainless steel with conductivity and corrosion resistance reinforced produced by etching its oxide layer, depositing metal nitride buffer layer on the etched surface and depositing conductive carbon layer on top of it in nano size thickness.

In addition, the present invention provides with stainless steel with conductivity and corrosion resistance reinforced wherein metal nitride comprise CrN or TiN and the thickness is 1 to 20 nm.

In addition, the present invention provides with stainless steel with conductivity and corrosion resistance reinforced wherein the conductive carbon layer thickness is 1 to 150 nm.

In addition, the present invention provides with stainless steel with conductivity and corrosion resistance reinforced wherein the stainless steel with conductivity and corrosion resistance is the fuel cell bipolar plate or electrodes.

In addition, the present invention provides with manufacturing system for nano carbon coating layer with conductivity and corrosion resistance which comprises #1 chamber for etching oxide layer of stainless steel by plasma, #2 chamber equipped with metal arc for coating metal nitride layer on the etched surface in #1 chamber and #3 chamber with ion gun for coating conductive carbon layer in nano size on the stainless steel surface coated with metal nitride layer in #2 chamber, the three chambers arranged in-line so that the plasma etching process, the metal nitride coating process and conductive carbon layer coating process would proceed consecutively in-situ.

Following is detail explanation on the preferable embodiments of the present invention by referring to attached figures.

The present invention enables the use of stainless steel as substrate material for fuel cell bipolar plate or electrode, or, provides with special stainless steel reinforced of properties by creating coating layers which improve the conductivity and corrosion resistance.

For this, first, the natural oxide layer of stainless steel is removed by plasma etching because the oxide layer may deteriorate conductivity. Then the corrosion resistance of stainless steel is reinforced by depositing metal nitride layer(200) on the etched surface with thickness of 1 to 20 nm. The conductivity is more improved by the removal of oxide layer on the surface of stainless steel by plasma etching process. At the same time, fine peaks and valleys with size of few nm's are formed on the surface and vitalized or activated. They improve the depositing rate and adhesiveness of coated film in the later coating process.

The corrosion resistance may usually decrease as conductivity increases by plasma etching; therefore, corrosion resistance is reinforced by coating on the etched surface metal nitride layer(200) including CrN or TiN with superior corrosion resistance in very thin thickness of 1 to 20 nm. Since metal nitride layer(200) have conductivity different from oxide layer, it is possible to improve corrosion resistance without decreasing conductivity.

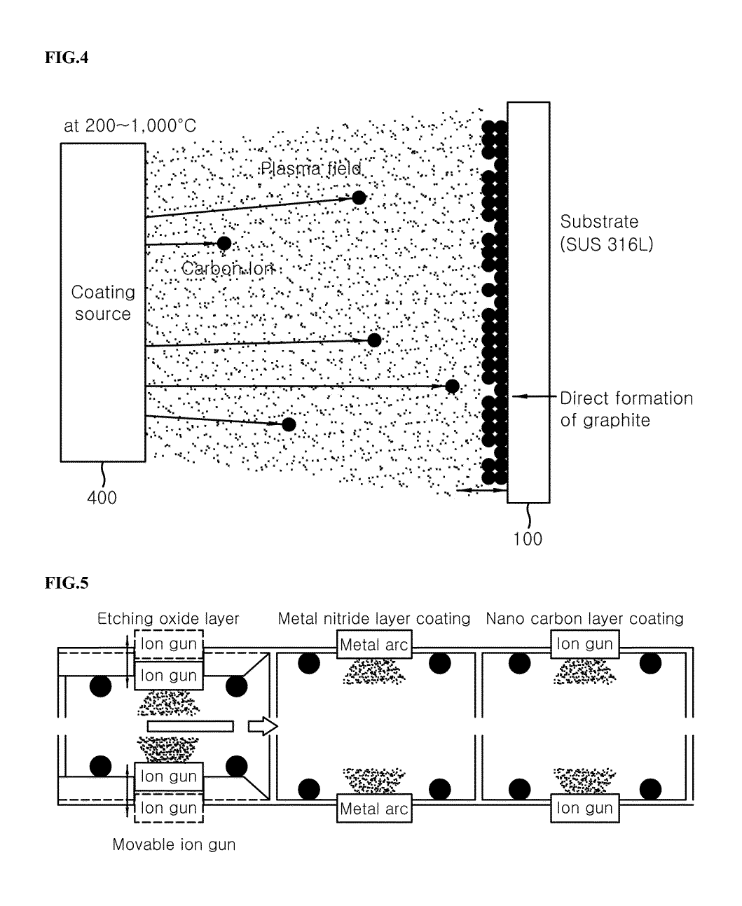

Then a conductive nano thickness carbon coating layer (300) would be coated on top of it with thickness of 1 to 150 nm in order to further improve conductivity. When the whole process has been completed, the coating layers would become like FIG. 3.

Above etching process and carbon coating process are performed by ion guns which provide with superior coating layer quality and high productivity (deposition rate) by generating high energy ions and they enable excellent plasma etching efficiency and dense coating layer with required properties but with nano size thin film.

In other words, the nano carbon coating, which improves the conductivity and corrosion resistance of stainless steel substrate, enables mass-production by including ion gun in-line system(Refer to FIG. 6).

All three of plasma etching step, metal nitride layer(200) coating step and conductive nano carbon coating layer (300) forming step go on by in-situ processes as in-line coating system. It is possible to construct in-line coating system because high-efficiency ion guns were adopted in both plasma etching process and carbon coating process, which enable sufficient properties even with nano size thickness. Conventional conductive carbon coating by PVD process should make thick film layer with thickness of 500 nm to few μm; because, otherwise, the coated film layer quality is not dense and there is a risk of exfoliation; therefore, it should go on for a long time, more than 5 hours, which makes mass-production not feasible. This demerit has been improved by the present invention. The development of manufacturing process and a system that enable mass-production has significant meaning in technical and economic values, because lowering the manufacturing cost of fuel cell bipolar plate is the key of relevant technology commercialization. The ion gun used in the present invention enables strong adhesiveness and high deposition rate, different from existing CVD process. Ion gun, which can generate particle energy as high as 700 eV, is used to keep coating thickness very thin but to improve the adhesiveness and fine tissue density so that economical efficiency and mass-production capabilities would be achieved [Refer to Andrew, S., Mike, A., Michael, K., Ken, N., Colin, Q., “Industrial Ion Sources and Their Application for DLC Coating,” presented at the SVC 42nd Annual Technical Conference, USA, Apr. 17-22, 1999]. Considering that the particle energy is as low as 2˜3 eV in existing PACVD process, the high energy particle generation by ion gun in the present invention greatly improve the process efficiency and layer quality. [Refer to Robertson, J., “Diamond-like amorphous carbon,” Materials Science and Engineering R 37:129-281, 2002]

Following is a practice example of the present invention. The manufacturing method of fuel cell bipolar plate is explained in detail together with attached figures and detail process conditions.

First, stainless steel which is prepared as substrate(100) of fuel cell bipolar plate shall be cleaned. The cleaning can be done by conventional technology using distilled water or isopropyl alcohol.

The cleaned substrate(100) would be put into a chamber. The natural oxide layer such as chrome oxide layer formed on the surface of stainless steel would be etched by plasma etching. Ion guns are prepared for plasma etching. Inert gas such as Ar or nitrogen gas would be charged to ion gun and 0.1 to 5 kW power (can be pulse, AC or DC power) is applied. By having the ions strike the substrate surface using discharged plasma, the oxide layer naturally formed on the stainless steel surface is removed by etching and the surface is activated. At this time, bias voltage is applied on the substrate(100) so that the ions would be pulled and etching can be more efficient. As shown in FIG. 5, the ion guns shall be positioned on upper side and rear side of substrate(100) so that both sides of substrate can be etched at the same time. Regarding the etching process, the etching rate changes dependent on the distance between substrate surface and ion gun as shown in FIG. 9; therefore, the ion guns would be movable so that they can be moved nearer to substrate for etching (Refer to FIG. 5).

In other words, etching rate y≈300/x. Here, x is the distance between ion gun and substrate surface. In this practice example, it was possible to increase the etching rate up to 4 times when the distance between ion gun and the specimen was reduced to 3 cm from 10 cm.

In this practice example, the plasma etching process for the removal of oxide layer is proceeded about 5 minutes while applying 250 W DC current on the ion gun and −100 V bias voltage on the substrate. FIG. 9 shows the FESEM analysis result of substrate surface for before and after the etching process. It is possible to see that the surface has become smoother. In addition, it was possible to know by measuring the surface roughness that the roughness improved by 20% after etching.

After the plasma etching process, a buffer layer would be formed on the etched and activated substrate surface in order to reinforce corrosion resistance. In other words, CrN or TiN metal nitride layer is coated in nano size thickness. This process can use the same process used in general depositing process such as PVD or PECVD. Process temperature would be from room temperature to 500° C., preferable between 300 to 500° C. and process pressure would be 10⁻² to 10⁻⁵ torr. In this practice example, relevant metal target and nitrogen are supplied to a chamber and PECVD is proceeded using metal arc. CrN or TiN metal nitride layer was coated as extremely thin film. It is possible to change coating duration time a bit dependent on other process variables such as power, pressure or temperature; however, it is recommended to have it 10 to 30 seconds but less than 5 minutes per one substrate.

In this practice example, the voltage on metal arc for metal nitride layer deposition was DC 10 to 30 V and the current was 30 to 200 A. 0 to −100 V bias voltage was applied to substrate. Caution is required because there can occur sputtering if the bias voltage would become beyond the above bias voltage. Coating of metal nitride improves the corrosion resistance of stainless steel substrate with oxide layer etched. CrN or TiN coating layer has conductivity as itself; therefore, it makes overall properties better together with high conductivity layer which will be coated later.

Next, it is possible to supply hydrocarbon gas or graphite target in the chamber as the source of carbon. Conductive carbon layer will be deposited by way of PVD or PECVD process. In this practice example, it was deposited by ion gun. 0.1 to 5 kW power (can be pulse power, AC power, or DC power) was applied to the ion gun. Process temperature would be 200 to 1000° C., desirably, 300 to 600° C. using a heater. Process pressure would be 10⁻² to 10⁻⁵ torr by way of supplying hydrocarbon gas. Conductive carbon coating layer would be deposited at the thickness of 1 to 150 nm, desirably 5 to 100 nm. FIG. 4 shows schematically the conductive carbon layer deposition process. At this time, it is recommended to apply bias voltage on substrate. Bias voltage would be applied as 0˜−800 V (−) voltage in DC, AC or pulse frequency (0.1 kHz˜500 kHz). This bias voltage prevents charge accumulation on the metal bipolar plate during conductive nano carbon coating and improves adhesiveness of metal bipolar plate substrate with carbon coating.

By way of above processes, the carbon layer becomes crystallized as soon as it is deposited by the energy of carbon itself, the heat energy applied from outside as seen from the temperature condition and the electric energy applied to substrate and forms conductive carbon layer in graphite state in-situ. Since the conductive nano carbon coating layer (300) has very thin nano size thickness, the process duration time is very short. It is possible to perform 360 coatings per hour and produce a fuel cell bipolar plate at the unit price of 2$ per plate in case of mass-production.

Compared to the conventional technology more than 500 nm thickness of carbon layer, in the present invention's example the thickness of the coating layers are less than 60 nm, including the carbon layer for the conductivity and the CrN layer for improving corrosion resistance. It means that the productivity is improved that much.

In addition, the contact resistance and corrosion current were measured for the manufactured fuel cell bipolar plate. In order to compare with this practice example, another specimen was prepared and it was directly deposited with conductive carbon layer with thickness of 50 nm without buffer layer of CrN or TiN and without etching of natural oxide layer of stainless steel substrate. The contact resistance and corrosion current of it were measured. As shown in FIG. 6, the result was that the contact resistance was 13.2 mΩcm²@10 kgf/cm² and corrosion current was 9.13 μA/cm² in the specimen shown in the left side comparison example; while the contact resistance was 13.7 mΩcm²@10 kgf/cm² and corrosion current was 0.42 0/cm² in this practice example. It is possible to know that the corrosion current was greatly lowered while keeping the contact resistance on the same level. It means that the fuel cell bipolar plate made by the present invention has good conductivity, has superior corrosion resistance and it can be produced in mass.

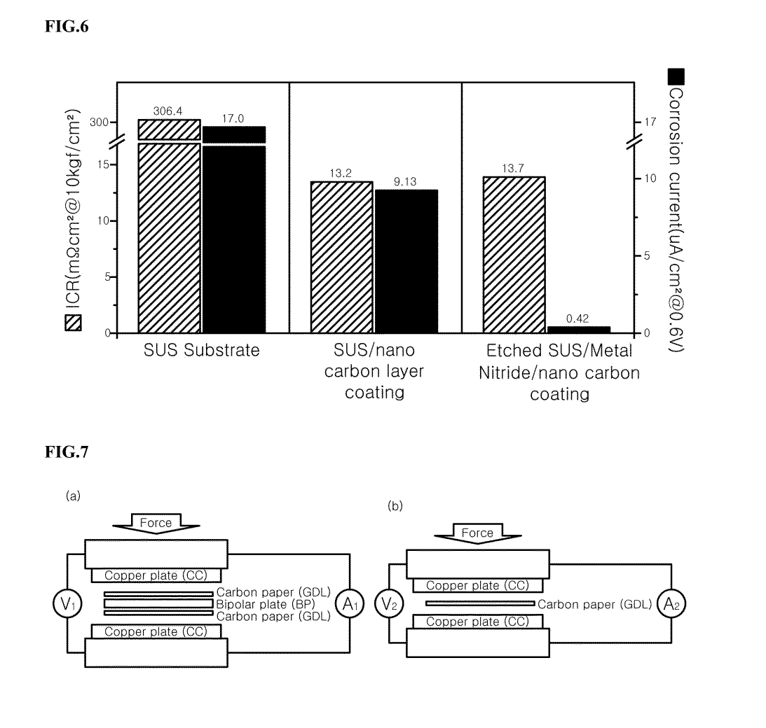

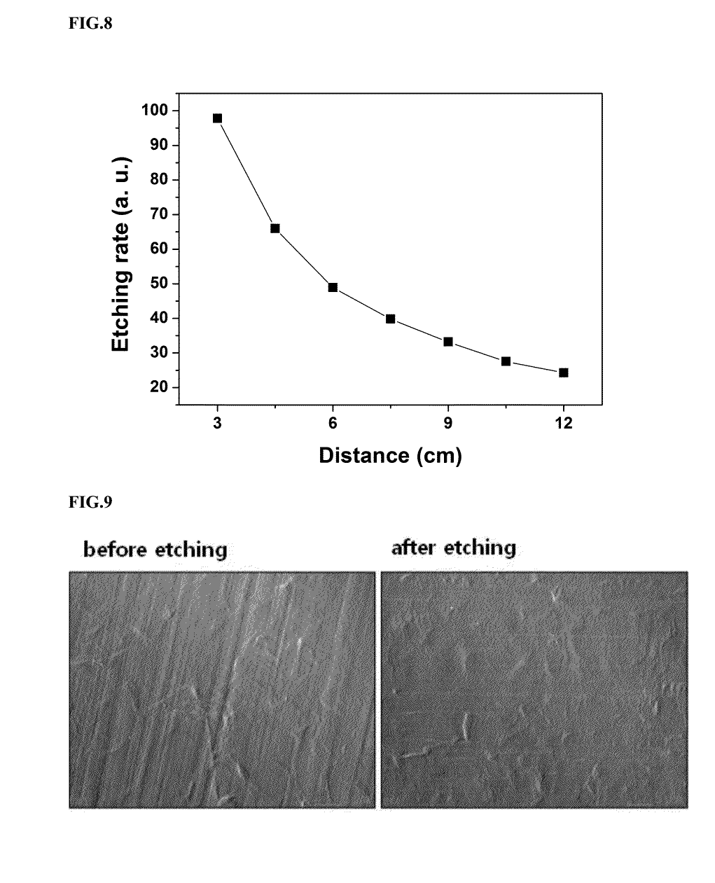

FIG. 7 shows the measuring method of fuel cell bipolar plate contact resistance prepared in this practice example. The contact resistance between bipolar plate and GDL (gas diffusion layer) was obtained by measuring the voltages at the both ends when applying current to the current collector at the upper part and the lower part while applying load of 10 kg per cm² of specimen. The contact resistance when bipolar plate is located between GDLs is measured first then the contact resistance of GDL itself is measured. Then the difference between the two was obtained.

It is possible to make corrosion resistant electrode material and special stainless steel in almost same way with the manufacturing of fuel cell bipolar plate applied of nano carbon coating in above practice example. The said process of the present invention can be applied on any other material as needed.

The right of the present invention is not limited to the practice example explained above. It is axiomatic that the right of the present invention is not limited to the working examples, which were explained above, but defined by what is written in the range of claims, and that the person with the general knowledge of this field can perform various changes and adapt within the range of right that is written in the range of claims.

What is claimed is:

1. A manufacturing system for a nano carbon coating layer with conductivity and corrosion resistance, comprising:
a first chamber configured for etching an oxide layer of stainless steel by plasma,
a second chamber equipped with metal arc configured for coating a metal nitride layer on an etched surface in the first chamber; and
a third chamber with an ion gun configured for coating a conductive carbon layer in nano size on a stainless steel surface coated with the metal nitride layer in the second chamber wherein the first, second, and third chambers are arranged in-line such that the plasma etching process, the metal nitride coating process and the conductive carbon layer coating process proceed with consecutively in-situ.
